(19) United States
(12) Patent Application Publication
(10) Pub. No.: US 2004/0107911 A1
(43) Pub. Date: Jun. 10, 2004

(54) Substrate support member for use in FPD manufacturing apparatus

(76) Inventors: Gwang Ho Hur, Yongin-shi (KR); Jun Young Choi, Seoul (KR); Cheol Won Lee, Anyang-shi (KR)

Correspondence Address: MORGAN & FINNEGAN, L.L.P., 345 Park Avenue, New York, NY, 10154-0053, US

(21) Appl. No.: 10/725,760

(22) Filed: Dec. 1, 2003

(30) Foreign Application Priority Data
Dec. 2, 2002 (KR) 2002-75764

(51) Int. Cl. C23C 16/00

(52) U.S. Cl. 118/728

(57) ABSTRACT

The present invention provides a substrate support member of an FPD manufacturing apparatus comprising: a substrate support plate on which a glass substrate is horizontally put, the substrate support plate having a plurality of vertical through-holes, each of the vertical though-holes having an upper distal portion of a shape of a reverse cone; and a plurality of lift pins being inserted into the respective vertical though-holes, the lift pins 32 being moved up and down so that the substrate 40 is raised from the substrate support plate 36 or put down on the substrate support plate 36, each of the lift pins having an upper distal portion of a shape of a reverse cone to comply with the upper distal portion of the corresponding vertical through-hole. According to the present invention, since the lift pins has a shape of a reverse cone, not a stick, to be closely contacted to the substrate support plate 36, the temperatures and the potentials are equal between the substrate support plate 36 and the each of the lift pins 32. Therefore, it is advantageous that any specks are not generated on the substrate 40, and film-formation and etching can be uniformly made.

### FIELD OF THE INVENTION

The present invention relates to a substrate support member in a flat panel display (hereinafter referred to as an FPD) manufacturing apparatus, and more specifically, a substrate support member for supporting a circumferential portion and a central portion of a glass substrate so that the glass substrate can not be bent when the substrate is raised or put down.

### BACKGROUND OF THE INVENTION

In general, an FPD manufacturing apparatus such as a dry etcher, a chemical vapor deposition apparatus, and a sputter comprises three vacuum chambers. The three vacuum chambers are a load-lock chamber, a process chamber, and a transfer chamber. The load-lock chamber is used for receiving a to-be-processed substrate and ejecting a process-completed substrate. The process chamber is used for performing a film-deposition process, an etching process, or the like by using a plasma or an energy. The transfer chamber is used for transferring the substrate from the load-lock chamber to the process chamber, or vice versa.

FIG. 1 is a plan view for explaining a structure of a conventional FPD manufacturing apparatus.

Referring to FIG. 1, a robot 22 is provided in a transfer chamber 20. The robot 22 has a hand for raising a glass substrate 40. The robot puts the substrate down on its hand and then conveys the substrate from a load-lock chamber 10 to a process chamber 30, or vice versa.

In the process chamber 30, a series of processes are carried out under the state that the substrate 40 is put on the substrate support plate 36. In addition, the substrate 40 is raised from the substrate support plate 36 or it is put down on the substrate support plate 36 by means of lift pins 32 or a lift bar 24.

The lift pins 32 are disposed on portions of the substrate support plate on which the substrate 40 is put down, and lift bar 34 is disposd at the exterior of the portion of the substrate support plate on which the substrate 40 is put down. The lift bar 34 has a curved portion at its upper distal portion. The curved portion has such a long length that the substrate 40 can be put on the lift bar 34 when the curved portion is directed to the substrate 40.

FIGS. 2a to 2f are cross-sectional views for explaining an operational method of the conventional FPD manufacturing apparatus.

When a series of processes are completed in the process chamber, the process-completed substrate 40b stands by for a second in a state of being put on the substrate support plate 36. At that time, a door between the transfer chamber 20 and the process chamber 30 is opened, and then, the robot 22 brings a to-be-processed substrate 40a into the process chamber 30. After that, the lift bar 34 is raised to support the substrate 40a, and then, the robot 22 leaves the process chamber 30 and returns to the transfer chamber 20 (see FIGS. 2a and 2b).

When the robot 22 returns to the transfer chamber 20, the lift pins 32 are raised to pick up the process-completed substrate 20b which is put on the substrate support plate 36. After that, the robot 22 located in the transfer chamber 29 enter the process chamber 30 again. At that time, the lift pins 32 are descended to put the substrate 40b down on the hand of the robot. The robot brings the process-completed substrate back into the transfer chamber 20 (see FIGS. 2c and 2d).

Next, the door between the transfer chamber 20 and the process chamber 30 is closed, and at the same time, the lift pins 32 and the lift bar 34 are descended to put the to-be-processed substrate 40a on the substrate support plate 36. After that, a sires of processes are carried out (see FIG. 2e).

On the other hand, the robot 22 located in the transfer chamber 20 puts the process-completed substrate 40b down on a substrate storage site (not shown) in the load-lock chamber 10, puts the stand-by substrate 40c on its hand, and rotates itself at 180 degree. In this state, the robot stands by at the transfer chamber 20 until the processes in the process chamber 30 are completed (see FIG. 2f).

In the meantime, a door between the load-lock chamber 10 and the transfer chamber 20 is closed, and then, the process-completed substrate 40b is ejected form the load-lock chamber 10. Next, another to-to-processed substrate (not shown) is entered into the load-lock chamber 10. By doing so, the substrates are exchanged. At that time, since it is preferable that the substrate are exchanged while the processes are carried out in the process chamber 30, it is necessary that the so-called venting and pumping of the load-lock chamber 10 are rapidly performed.

FIGS. 3a and 3b are views for explaining problems of a substrate support member of the FPD manufacturing apparatus of FIG. 1.

As shown in FIG. 3a, the aforementioned conventional FPD manufacturing apparatus, the lift pins 32 are disposed at the distance of 15 mm from the edge of the site on the substrate support plate on which the substrate 40 is put. In other words, the lift pins 32 are not disposed at the location on which the central portion of the substrate 40 is put.

As shown in FIG. 3b, when the substrate 40 is put on the substrate support plate 36, a temperature difference or a potential difference is created between the locations A where the lift pins 32 are disposed and the other locations where the lift pins 32 are not disposed. Therefore, since etch rates are different among the locations A and the other locations, there are specks 45 on the surface of the substrate 40 after the etching process. For this reason, the lift pins 32 can be disposed not at the central portion but at the circumferential portion of the substrate 40.

However, the size of the substrate has recently been widened up to about 2 m×2 m. If the wide substrate 40 is raised and transferred by being supported at only its circumferential locations like the conventional method, there occurs severe bending of the central portion of the substrate 40, so that the substrate 40 may be broken and the transfer of the substrate may be impossible because of the robot being prevented from moving below the substrate 40.

In addition, as shown in FIG. 3b, if there is a gap between each of the lift pins 32 and the corresponding vertical though-hole 31 formed in the substrate support plate, an impurity such as a gas in the process chamber during a certain process is introduced into the gap and remains, and after that, it is emitted into the process chamber during another process, so that the accuracy of the process may be lowered.

In addition, if there is a gap between each of the lift pins 32 and the corresponding vertical though-hole 31, an impurity is introduced into the gap, so that the lift pins 32 may be contaminated or eroded.

### SUMMARY OF INVENTION

In order to solve the above mentioned problems, an object of the present invention is to provide a substrate support member for supporting a central portion as well as a circumferential portion of a glass substrate, so that the glass substrate can not be bent when the substrate is raised or put down.

In order to achieve the object, a substrate support member of an FPD manufacturing apparatus according to the present invention comprises: a substrate support plate on which a glass substrate is horizontally put, the substrate support plate having a plurality of vertical through-holes, each of the vertical though-holes having an upper distal portion of a shape of a reverse cone; and a plurality of lift pins being inserted into the respective vertical though-holes, the lift pins being moved up and down, so that the substrate is raised from the substrate support plate or it is put down on the substrate support plate, each of the lift pins having an upper distal portion of a shape of a reverse cone to comply with the upper distal portion of the corresponding vertical through-hole.

In the aforementioned substrate support member according to the present invention, it is preferable that, in a case where the only one of each of the lift pins and the substrate support plate has an insulated surface, the lift pins are electrically connected to the substrate support plate by an additional means or by a contact of a lower portion of each of the lift pins (having a shape of reverse-cone) and a removed portion of a insulation film on the substrate support plate.

### BRIEF DESCRIPTION OF THE DRAWINGS

The aforementioned aspects and other features of the present invention will be explained in the following description, taken in conjunction with the accompanying drawings, wherein:

FIG. 1 is a plan view for explaining a conventional FPD manufacturing apparatus;

FIGS. 2a to 2f are cross-sectional views for explaining an operational method of the FPD manufacturing apparatus of FIG. 1;

FIGS. 3a and 3b are views for explaining problems of a substrate support member of the FPD manufacturing apparatus of FIG. 1; and

FIGS. 4 are a cross-sectional view for explaining a substrate support member of an FPD manufacturing apparatus according to the present invention.

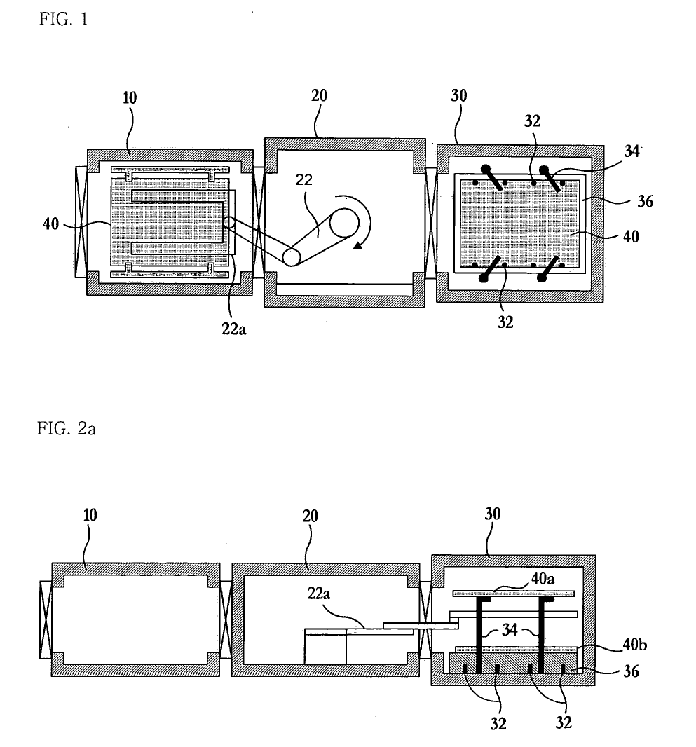

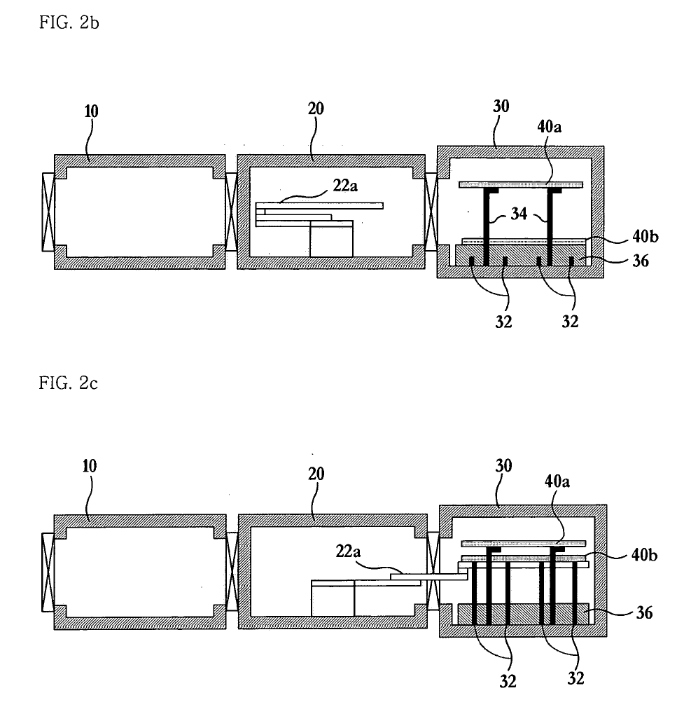

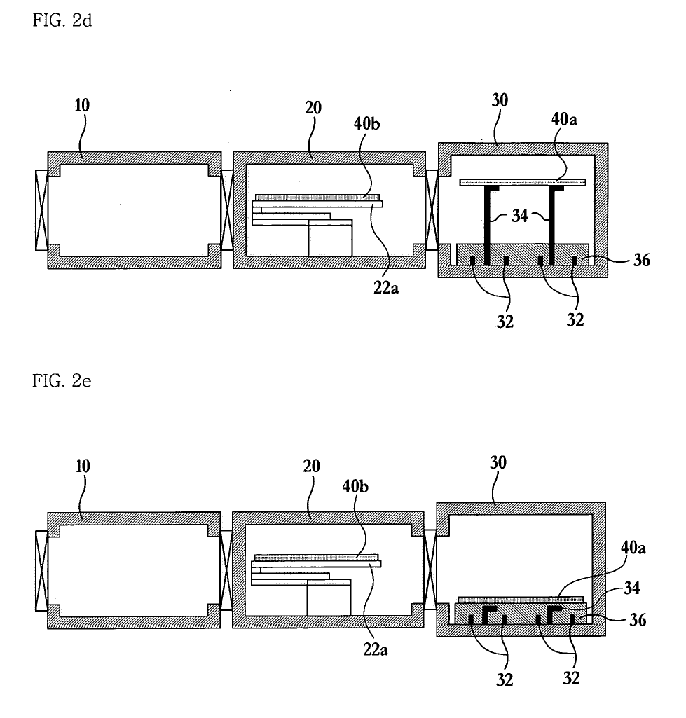

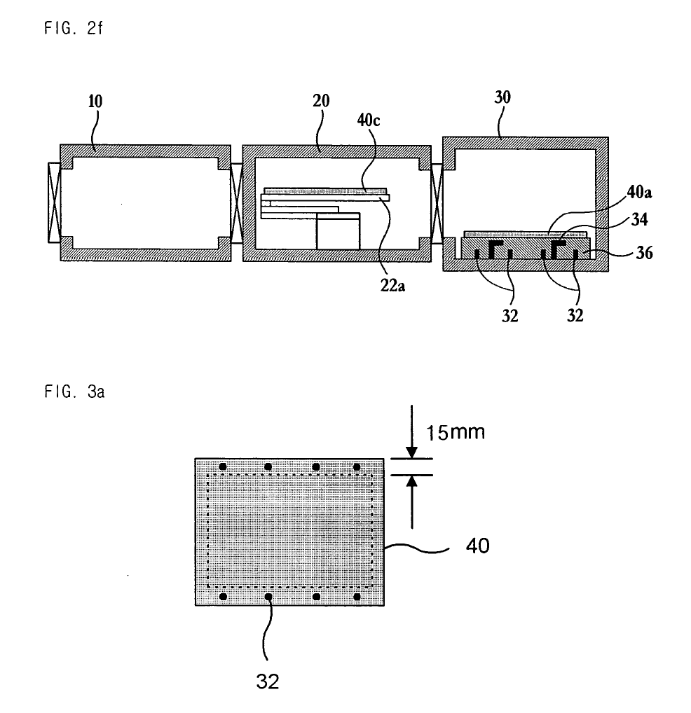

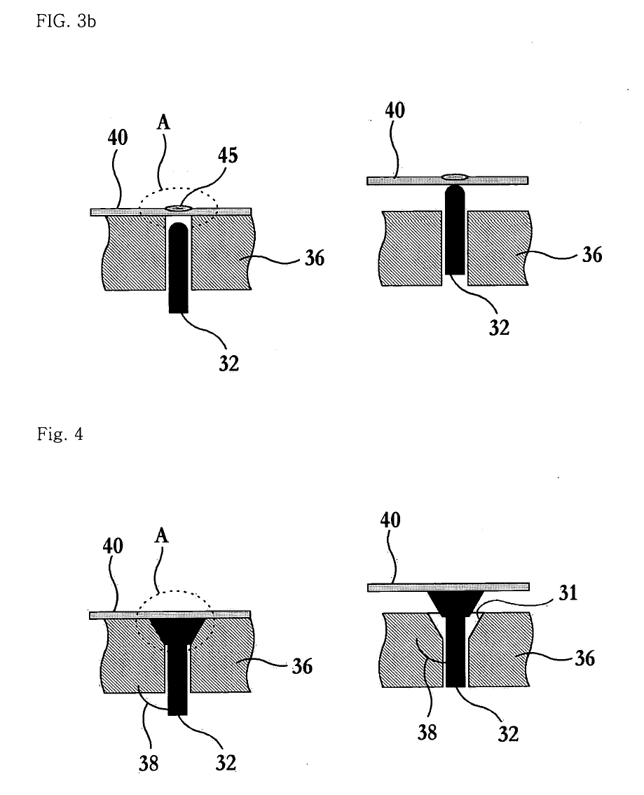

### DETAILED DESCRIPTION OF THE PREFERRED EMBODIMENTS

Now, the preferred embodiments according to the present invention will be described in detail with reference to the accompanying drawings. Herein, the only characteristics of the present invention will be described, and the description on the same component as the conventional technique will be omited.

FIG. 4 are a cross-sectional view for explaining a substrate support member of an FPD manufacturing apparatus according to the present invention.

As shown in FIG. 4, a glass substrate 40 is horizontally put on a substrate support plate 36. The substrate support plate 36 comprises a plurality of vertical through-holes 31. In addition, a plurality of lift pins 32 which are inserted into the respective vertical though-holes 31 can be moved up and down. By the up-down movement of each of the lift pins 32, the substrate 40 is raised from the substrate support plate 36, or it is put down on the substrate support plate 36.

In order to prevent the temperature difference and the potential difference between the aforementioned locations A where the lift pins 32 are disposed and the other locations where the lift pins are not disposed, it is preferable that the lift pins 32 are electrically and thermally connected to the substrate support plate 36. As shown in FIG. 4, the upper distal portion of each of the vertical though-holes 31 is formed in a shape of a reverse cone, and the upper distal portion of each of the lift pins 32 is formed in a shape of a reverse cone to comply with the upper distal portion of the corresponding vertical through-hole 31. Since each of the lift pins and each of the vertical through-holes 31 are complied with each other in geometrical structure, the lift pins are closely contacted to the respective vertical though-holes when the lift pins are descended. Therefore, the lift pins 32 are electrically and thermally connected to the substrate support plate.

In addition, when the lift pins 32 are descended, the lift pins 32 are tightly inserted into the vertical through-holes 31. Therefore, the top plane of the substrate support plate 36 is continuous with the top plane of each of the lift pins 32 without any gaps. Since there are no gaps between the substrate support plate 36 and the lift pins 32, an impurity such as a gas generated during the process can not be introduced. Accordingly, the problem that the process chamber is contaminated or eroded during the other processes can be solved.

In addition, it is preferable that the lift pins 32 and the substrate support plate 36 are made up of a metal. In the case that the lift pins 32 and the substrate support plate 36 are made up of a metal which has good thermal and electric conductivities, the aforementioned close contact leads to the thermal and electrical connection between them, so that the temperature and potential differences can not be created. In order to maximize the effect, it is further preferable that the lift pins 32 and the substrate support plate 36 are made up of the same metal.

On the other hand, the upper portion of each of the lift pins 32 of the present invention has larger volume than that of the conventional lift pins. Therefore, each of the lift pins of the present invention has a large thermal capacitance, so that it is less sensitive to change of the temperature of the substrate 40. Accordingly, on the substrate support plate, the temperature difference is smaller between the locations where the lift pins 32 are disposed and the other locations where the lift pins are not disposed.

However, in the case that the only one of the substrate support plate 36 and each of the lift pins 32 has an insulated, current can not be conducted between the substrate support plate 36 and each of the lift pins 32, so that the equal potential may not be obtained. Therefore, in this case, it is preferable that the lift pins are electrically connected to the substrate support plate by an additional means.

For example, even though the substrate support plate 36 is typically made up of a metal, the substrate support plate used for a plasma process apparatus is insulated by an anodizing process. In this case, it is preferable that the lift pins 32 are electrically connected to the substrate support plate 36 by removing the insulation material on some portion of the anodized site or by an addition electrical wire 38 in order to obtain the equal potential between them.

In this way, according to the present invention, the lift pins 32 are provided not to create the temperature and potential differences on the substrate support plate. In addition, the lift pins are provided to have large area of contacting with the glass substrate 40. Accordingly, the pressure exerted on the unit area of the glass substrate is so small that the glass substrate can not be easily deformed. The lift pins 32 according to the present invention are suitable to support the circumferential portions of the substrate support plate 40, and moreover, the central portion of substrate support plate 40.

According to the present invention, since the lift pins 32 have a shape of a reverse cone, not a stick, to be closely contacted to the substrate support plate 36, the temperatures and the potentials are equal between the substrate support plate 36 and the each of the lift pins 32. Therefore, it is advantageous that any specks are not generated on the substrate 40, and film-formation and etching can be uniformly made.

In addition, since the upper plane of each of the lift pins according to the present invention has a large area, the lift pins can support a large area of the substrate. Accordingly, it is advantageous that there is no need of increasing the number of the lift pins even in the large-area substrate.

In addition, since the lift pins according to the present invention are completely inserted into the though-holes formed on the substrate support plate, it is advantageous that the lift pins are not contaminated.

In addition, since the lift pins according to the present invention are suitable to support the central portion of the large-area substrate, it is advantageous that the central portion of the large-area substrate is not bent.

Although the foregoing description has been made with reference to the preferred embodiments, it is to be understood that changes and modifications of the present invention may be made by the ordinary skilled in the art without departing from the spirit and scope of the present invention and appended claims.

What is claimed is:

1. A substrate support member of an FPD manufacturing apparatus, comprising:
a substrate support plate on which a glass substrate is horizontally put, the substrate support plate having a plurality of vertical through-holes, each of the vertical though-holes having an upper distal portion of a shape of a reverse cone; and
a plurality of lift pins being inserted into the respective vertical though-holes, the lift pins being moved up and down so that the substrate 40 is raised from the substrate support plate or put down on the substrate support plate, each of the lift pins having an upper distal portion of a shape of a reverse cone to comply with the upper distal portion of the corresponding vertical through-hole.

2. The substrate support member of an FPD manufacturing apparatus according to claim 1, wherein the lift pins are made up of a material which is the same as that of the substrate support plate.

3. The substrate support member of an FPD manufacturing apparatus according to claim 1, wherein the lift pins and the substrate support plate are made up of a metal.

4. The substrate support member of an FPD manufacturing apparatus according to claim 1, wherein the lift pins are electrically connected to the substrate support plate.

5. The substrate support member of an FPD manufacturing apparatus according to claim 4, wherein the lift pins are electrically connected to the substrate support plate by additional connection lines.

6. The substrate support member of an FPD manufacturing apparatus according to claim 4, wherein the lift pins are electrically connected to the substrate support plate by removing some portion of an insulating material provided on an exterior of the substrate support plate.

7. The substrate support member of an FPD manufacturing apparatus according to claim 1, wherein the lift pins are disposed to support a central portion of the substrate.
